(19) United States
(12) Patent Application Publication
(10) Pub. No.: US 2025/0316956 A1
(43) Pub. Date: Oct. 9, 2025

(54) DIFFERENTIALLY-DRIVEN ELECTRO-ABSORPTION MODULATOR

(71) Applicant: II-VI Delaware, Inc., Wilmington, DE (US)

(72) Inventors: Andrei KAIKKONEN, Wilmington, DE (US); David ADAMS, Wilmington, DE (US); Lennart LUNDQVIST, Wilmington, DE (US); Nicolae CHITICA, Wilmington, DE (US); Robert LEWÉN, Wilmington, DE (US)

(73) Assignee: II-VI Delaware, Inc., Wilmington, DE (US)

(21) Appl. No.: 19/095,912

(22) Filed: Mar. 31, 2025

Related U.S. Application Data
(60) Provisional application No. 63/631,335, filed on Apr. 8, 2024.

(51) Int. Cl. H01S 5/042; H01S 5/02251; H03F 3/45

(52) U.S. Cl. CPC H01S 5/042; H01S 5/02251; H03F 3/45475

(57) ABSTRACT

Apparatus is disclosed for generating and modulating the power of a laser beam to be transmitted in an optical communication fiber. The apparatus includes a laser source and an electro-absorption modulator located on a common insulating or semi-insulating substrate. The laser source generates the laser beam. A high-frequency electrical signal encodes data to be transmitted by the modulated laser beam. The modulator is differentially driven by the electrical signal, which is terminated on the common substrate to minimize cross talk with other data channels. Traveling-wave electrodes connecting segments of the modulator and a termination network maintain electrical signal integrity and minimize losses.

### CROSS-REFERENCE TO RELATED APPLICATIONS

This application claims the benefit of U.S. Provisional Application No. 63/631,335, filed Apr. 8, 2024, the entire contents of which is incorporated by reference herein.

### TECHNICAL FIELD OF THE INVENTION

The present invention relates in general to modulation of an optical signal for transmission in an optical fiber. The invention relates in particular to rapid modulation of an optical signal by a differentially-driven electro-absorption modulator.

### DISCUSSION OF BACKGROUND ART

Optical fibers are ubiquitous for high-speed data transmission. There are optical transmitters and optical receivers at each end of an optical fiber to convert an electrical signal to an optical signal for transmission and to convert a received optical signal to an electrical signal. A transmitter typically includes a laser to produce a laser beam that will be encoded with the data signal to be transmitted. The data signal may be digital, a pulse amplitude modulation (PAM), or otherwise encoded. The data signal may be impressed on the laser beam by directly modulating the electrical signal driving the laser or by modulating the power of the laser beam itself using an optical modulator. The latter has the optical modulator arranged to intercept the laser beam and is known as an “externally modulated laser” (EML). In an “electro-absorption modulator” (EAM), an electrical drive signal regulates its optical absorption, thereby impressing a data signal onto a laser beam that is partially transmitted therethrough.

There may be additional components at each end of the optical fiber, such as optical switches, multiplexers, and demultiplexers. There may be components between each end, particularly fiber amplifiers, which periodically amplify laser beams guided within a long optical fiber. In commercial implementations, the optical transmitter(s) and optical receiver(s) at each end of the optical fiber may be integrated into a single device called an “optical transceiver”. Currently, optical transceivers are commercially available at data rates of up to 800 Gb/s (gigabits per second). For example, from Coherent Corp. of Saxonburg, Pennsylvania.

### SUMMARY OF THE INVENTION

The market is demanding even faster optical transceivers, while maintaining high reliability, high efficiency, broad temperature tolerance, good wavelength control, minimal power consumption, and standard form factors. Another critical requirement is low cross talk between transmitter channels, between receiver channels, and between transmitter and receiver channels. A typical transceiver has four or eight transmitter channels and four or eight receiver channels. Cross talk increases bit error rate (BER) and effectively reduces receiver sensitivity. Cross talk generally increases with increasing data rates. There is need for EML designs that minimize cross talk to enable high performance optical transceivers at higher data rates.

An EAM and a laser may be combined into a single component or they may be separate components. In both implementations, the EAM is single-end driven, with the other end being electrical ground. Typically, an RF electrical potential drives the anode of the EAM, while the cathode is grounded. A disadvantage of this traditional implementation is unwanted electrical cross talk between transmitter channels and between transmitter and receiver channels. In long-distance communication, the received signal produced by a photodiode is often much weaker than the signal driving the transmitter, which may cause significant transmitter-to-receiver cross talk within a transceiver.

Disclosed herein are laser transmitting devices wherein an optical modulator is differentially driven at very-high frequencies corresponding to the transmission data rate. An RF electrical potential drives the optical modulator anode and cathode simultaneously, with opposing “push-pull” potentials. The optical modulator is differentially driven in embodiments having the laser source and the optical modulator located on a common substrate and embodiments where they are separated. The inventors recognized that these components can be located on a common substrate made of a highly resistive material, albeit one that is not strictly electrically insulating. This includes semi-conducting materials, thereby enabling precise low-cost high-volume fabrication. EML are disclosed herein, with features and arrangements that minimize electrical coupling between an optical modulator and other active elements on the substrate, such as a laser source.

The inventors also recognized that the high-frequency differential drive signal may be electrically terminated by components located on the same substrate as the optical modulator. Laser transmitting devices are disclosed using an RF termination network to terminate the differential drive signal on the substrate and thereby isolate the differential drive signal to the substrate. Embodiments are disclosed having one optical modulator, a segmented optical modulator, or a plurality of optical modulators. A segmented optical modulator or plurality or optical modulators may be incorporated into an electrical transmission line for delivering the differential drive signal thereto, which minimizes signal losses and distortion. EML are disclosed that include segmented optical modulators, transmission lines for delivering a differential drive signal to modulator segments, and termination of differential drive signals on the same substrate as the modulator segments. These features and arrangements mitigate cross talk when the disclosed laser transmitting devices are operating in an optical transceiver.

Another advantage of differentially driving an optical modulator is a near doubling of the optical modulation obtained for a given input RF electrical power, compared to single-end driving. The push-pull mode of operation modulates the electrical potential applied to an EAM about a constant bias electric potential. Differential driving effectively doubles the electric potential changes across an EAM, thereby doubling the optical modulation amplitude and doubling the optical extinction ratio, without increasing the RF power consumed.

In one aspect, a laser transmitting device in accordance with the present invention comprises an electrically insulating or semi-insulating substrate, a laser source located on the substrate producing a laser beam, and at least two optical modulators also located on the substrate and intercepting the laser beam. Each optical modulator has an n-side and a p-side. A differential amplifier has an electrical input and an electrical output. The electrical output is applied differentially across the optical modulators. The electrical output regulates transmission of the laser beam through the optical modulators. The device further comprises a termination network and further comprises first and second traveling-wave electrodes. The first traveling-wave electrode inductively connects the n-sides of the optical modulators. The second traveling-wave electrode inductively connects the p-sides of the optical modulators. The first and second traveling-wave electrodes are electrically connected to the termination network.

In another aspect of the present invention, a laser transmitting device comprises an electrically insulating or semi-insulating substrate, a laser source located on the substrate producing a laser beam, an optical modulator also located on the substrate and intercepting the laser beam, and a differential amplifier having an electrical input and an electrical output. The electrical output is applied differentially across the optical modulator. The electrical output regulates transmission of the laser beam through the optical modulator. A termination network is electrically connected across the optical modulator. The termination network includes first and second capacitors. The first and second capacitors are each in parallel with the optical modulator. The first and second capacitors cooperatively maintain a bias potential across the optical modulator. The first capacitor is located off the substrate, while the second capacitor is located on the substrate. The capacitance of the first capacitor is greater than capacitance of the second capacitor.

### BRIEF DESCRIPTION OF THE DRAWINGS

The accompanying drawings, which are incorporated in and constitute a part of the specification, schematically illustrate a preferred embodiment of the present invention, and together with the general description provided above and the detailed description of the preferred embodiment provided below, serve to explain principles of the present invention.

FIG. 1 is an electrical block diagram schematically illustrating one preferred embodiment of laser transmitting device in accordance with the present invention, including a laser source and an optical modulator located on a common substrate, a bias potential, a RF termination network, and a differential amplifier applying a rapidly-modulated electric potential differentially across the optical modulator.

FIG. 2 is a perspective view schematically illustrating a preferred embodiment of externally modulated laser in accordance with the present invention, which may be incorporated into the device of FIG. 1.

FIG. 3 is an electrical block diagram schematically illustrating another preferred embodiment of laser transmitting device in accordance with the present invention, similar to the device of FIG. 1, but having the optical modulator located on a substrate separate from the laser source, with elements of the termination network located on the substrate to provide electrical termination for the rapidly-modulated electric potential.

FIG. 4 is an electrical block diagram schematically illustrating yet another preferred embodiment of laser transmitting device in accordance with the present invention, similar to the device of FIG. 3, but having two optical modulators and inductors arranged to form a transmission line for the rapidly-modulated electric potential.

FIGS. 5A and 5B are perspective views schematically illustrating another preferred embodiment of EML in accordance with the present invention, which may be incorporated into the device of FIG. 4.

FIG. 6 is a cross-sectional view schematically illustrating yet another preferred embodiment of EML in accordance with the present invention, which includes the elements of the EML of FIGS. 5A and 5B, and elements of the termination network of FIG. 4.

FIG. 7 is a cross-sectional view schematically illustrating still another preferred embodiment of EML in accordance with the present invention, similar to the EML of FIG. 6, but having a different structure.

FIG. 8A is a grayscale histogram of receiver signal density for receiver signal vs. time in a simulated transceiver containing laser transmitting devices similar to FIG. 1, with the termination network located off the substrate of the optical modulator.

FIG. 8B is a grayscale histogram of receiver signal density for receiver signal vs. time in a simulated transceiver containing the laser transmitting devices of FIG. 3., with elements of the termination network located on the same substrate as the optical modulator.

FIGS. 9A and 9B respectively are plots of bit error rate for the same transceivers as FIGS. 8A and 8B, represented by contours of equal BER, simulated with and without transmitter-to-receiver cross talk.

### DETAILED DESCRIPTION OF THE INVENTION

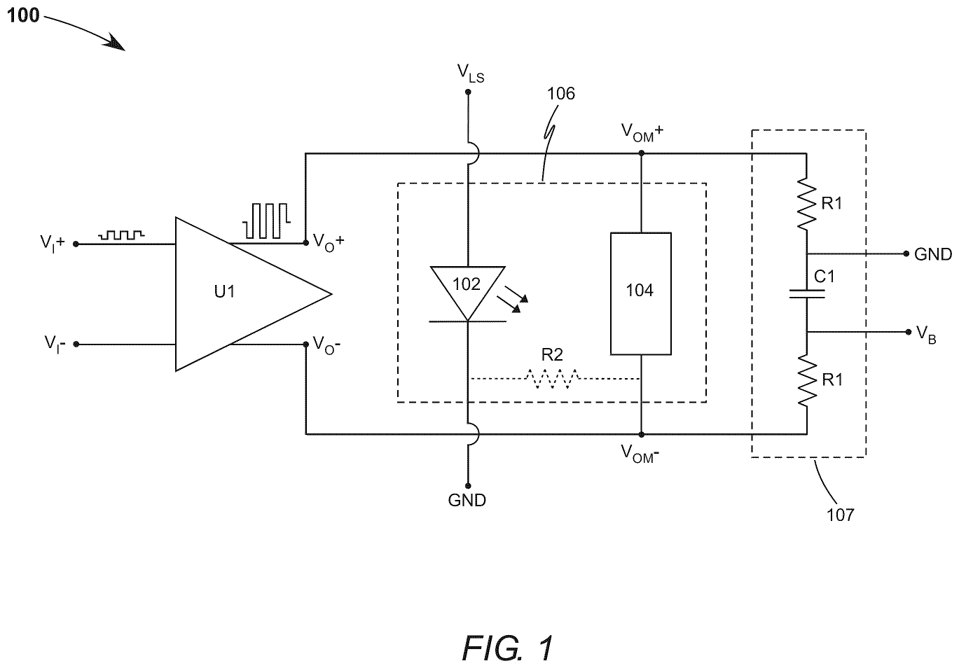

Turning now to the drawings, wherein like features are designated by like numerals, FIG. 1 schematically illustrates one embodiment of a laser transmitting device 100 in accordance with the present invention. Device 100 comprises a laser source 102 and an optical modulator 104 located on a common substrate 106. In operation, a laser beam (not depicted) may be produced by laser source 102 and intercepted by optical modulator 104. Substrate 106 may be made of an electrically insulating material, a material with low electrical conductivity, or a semiconductor. Herein, low-electrical-conductivity materials or low-electrical conductivity semiconductor materials will be referred to as “semi insulating”. A low-electrical conductivity material may have a resistivity greater than 10 Ωm (ohm·meters). Semiconductor materials may have inherently low conductivity, may have low conductivity due to environmental conditions (for example, at low temperatures), or may have low conductivity due to dopants.

There are advantages to fabricating laser source 102 and optical modulator 104 on the same substrate. The physical proximity of optical modulator 104 to laser source 102 helps to minimize optical losses therebetween. Locating laser source 102 and optical modulator 104 on a common substrate enables them to be optically coupled via a waveguide, as described herein below. Waveguide optical coupling is invulnerable to mechanical instabilities compared to free-space optical coupling.

When substrate 106 is made of a semiconductor material such as silicon or indium phosphide (InP), all the fabrication processes and tooling used in the semiconductor industry become available, including: deposition, doping, etching, metallization, heterogeneous integration, and dicing. Such processes and tooling enable large scale manufacturing at relatively low cost per device. It is also possible to locate laser source 102 and optical modulator 104 on a glass substrate or a crystalline substrate such as lithium niobate. Fabricating an integrated device means laser source 102 and optical modulator 104 can be made by sharing some of the same processing steps for efficiency. An integrated device also eliminates the steps otherwise needed to assemble the separate components together.

Laser source 102 is driven by an electrical potential V_{LS}. In general, V_{LS} will induce a direct current above the lasing threshold such that laser source 102 produces the laser beam with about constant optical power. Laser source 102 may thereby produce a continuous wave laser beam. In some embodiments, laser source 102 is a semiconductor resonator (a laser diode). Alternatively, laser source 102 may be a semiconductor optical amplifier, which amplifies a laser beam generated by a laser that may be located on the same substrate as the semiconductor optical amplifier or may be located remotely. A waveguide may couple the laser beam from the laser to the semiconductor optical amplifier.

Optical modulator 104 regulates transmission of the laser beam propagating therethrough by partially absorbing the laser beam, by partially reflecting the laser beam, or by changing a phase of the laser beam. Herein, for convenience of description, examples using absorption will be presented in detail.

A bias driver (not depicted) provides a reverse bias electric potential V_{B}, which is applied across optical modulator 104, between nodes V_{OM}⁺ and V_{OM}⁻. In operation, the bias potential is preferably constant. A differential amplifier U1 simultaneously applies a rapidly modulated electrical potential differentially between nodes V_{OM}⁺ and V_{OM}⁻. In operation, this modulated potential comprises a data signal to be transmitted by device 100. The modulated potential regulates transmission of the laser beam through optical modulator 104.

The bias potential V_{B} may be selected so that the modulator produces the largest absorption and transmission changes in response to the modulated potential applied by differential amplifier U1. That condition may typically correspond to a reverse bias potential V_{B} of 1.5 V. Bias potential VB may typically be kept constant during operation, but may be adjusted to accommodate temperature changes within the modulator, and this setting may be calibrated. For example, a smaller bias potential may be set when the modulator is hotter. It should be noted that the polarity of bias voltage V_{B} with respect to ground may be selected for convenience of implementation. Here, reverse biasing of optical modulator 104 corresponds to a positive bias voltage V_{B}.

Device 100 further includes a passive RF termination network 107 electrically connected across optical modulator 104. Termination network 107 comprises a capacitor C1 and two resistors R1. Capacitor C1 maintains the bias potential across optical modulator 104 during operation when the data signal is also being applied by differential amplifier U1. C1 may typically have a capacitance of 100 nF (nano farad). Resistors R1 allow the rapid modulation of the overall potential across optical modulator 104. Resistors R1 may have a resistance of 30 Ω(ohms) each. The resistance may be a compromise that targets a characteristic impedance for the driving circuit. The selected resistance must be sufficient to enable rapid modulation, but not so high as to limit the accessible modulation bandwidth.

Differential amplifier U1 has electrical inputs V_{I}⁺ and V_{I}⁻ and electrical outputs V_{O}⁺ and V_{O}⁻. The data signal (depicted in the drawing as a pulsed waveform) is applied across the electrical inputs. A conditioned and amplified data signal (depicted in the drawing as a larger amplitude pulsed waveform) from the electrical outputs is applied differentially across optical modulator 104. The amplified data signal may be up to 2 V peak-to-peak between V_{O}⁺ and V_{O}⁻. Combined with a reverse bias potential V_{B} of 1.5 V, the potential between V_{OM}⁺ and V_{OM}⁻ may be modulated between 1.0 V and 2.0 V, or even between 0.5V and 2.5 V. That may correspond to an optical absorption loss modulated between 4 dB and 10 dB. The data rate corresponding to the modulation frequency of the data signal may be greater than 10 Gb/s. For example, the data rate may be up to 200 Gb/s. By parallel combination of multiple optical modulators within a transceiver, the aggregate transmitted data rate may be higher. For example, 800 Gb/s for a transceiver with four parallel 200 Gb/s optical modulators. Devices with even higher data rates are envisaged, such as 1.6 Tb/s (terabits per second) or 3.2 Tb/s, by combining additional optical modulators, increasing the data rate, or adding more PAM levels.

Termination network 107 may be located off substrate 106. For example, termination network 107 may be located on a different substrate from substrate 106 or on a circuit board separate from substrate 106. Similarly, differential amplifier U1 may be located off substrate 106, as depicted.

There may be current leakage between laser source 102 and optical modulator 104, which are both located on semi-insulating substrate 106. The pathway for current leakage is represented in the block diagram by a resistor having a resistance R2. Device 100 is depicted with the cathode side of laser source 102 connected to electrical ground and optical modulator 104 is therefore isolated from electrical ground by the substrate 106. If substrate 106 is made of indium phosphide, resistance R2 may be a few kilo-ohms (kΩ). For example, resistance R2 may be at least 1 kΩ, may be 2 kΩ, or may be at least 5 kΩ. Ideally, there may be no current leakage. Embodiments to achieve such resistances are described herein below. Too much current leakage increases electrical power consumption and may cause unwanted heating. However, a resistance R2 of 1 kΩmay still be enough for acceptable operation.

The differential driving of optical modulator 104 in device 100 reduces cross talk between transmitter channels and reduces cross talk between transmitter and receiver channels compared to conventional single-end driven devices. The cross-talk on another transmitter channel or on a receiver channel may be less than −20 dB, preferably may be less than −25 dB, or more preferably may be less than −30 dB.

At high data rates, the electrical connection of the optical modulator(s) to a common electrical ground in conventional devices becomes an unwanted source of RF noise in a transceiver. For this reason, device 100 may be particularly useful for data rates of 200 Gb/s or greater. Differential driving is also less susceptible to electrical noise than single-end driving. Electrical noise can induce voltage noise in the high-frequency circuit of a single-end device. However, common-mode voltage noise in the differentially driven circuit of device 100 cannot induce absorption changes in optical modulator 104.

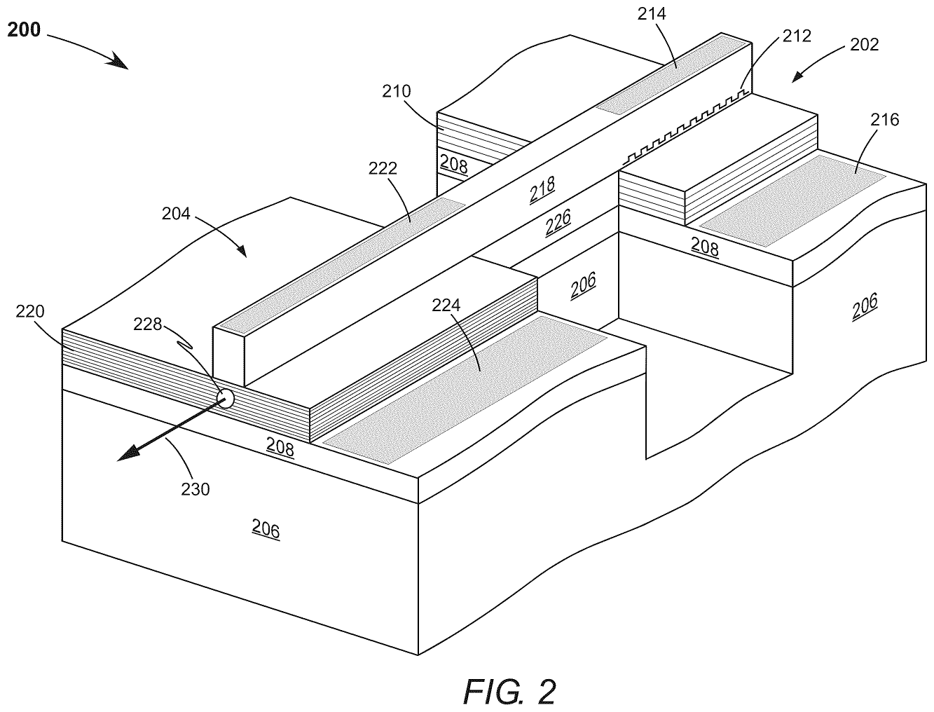

FIG. 2 is a perspective view schematically illustrating one example of an externally modulated laser 200 comprising a substrate 206, a laser source 202, and an optical modulator 204. EML 200 is an embodiment where substrate 206 is made of a semiconducting material, such as indium phosphide. Layer 208 may then be an n-type doped layer of indium phosphide, located directly on top of substrate 206. Laser source 202 and optical modulator 204 are located directly on top of layer 208. Herein, words such as “top”, “bottom”, “horizontal”, and “vertical” are for purposes of description and do not correspond to specific orientations in use.

Laser 202 comprises a laser active region 210, an optional grating 212, a p-side electrode 214, an n-side electrode 216, and a ridge 218. Laser active region 210 is an epitaxially-grown structure, including layers that define the quantum wells producing the laser light. Grating 212 is embedded in a p-type layer and is close enough to laser active region 210 be within an evanescent field of the laser light. In this arrangement, laser 202 is a distributed feedback laser. Grating 212 selects a lasing wavelength within a gain spectrum of laser active region 210. Other arrangements are possible. For example, a distributed Bragg reflector laser, having a grating incorporated into a passive waveguide section(s) located at one or both ends of laser active region 210.

A driving potential (V_{LS} in FIG. 1) is applied to p-side electrode 214 and n-side electrode 216 is connected to electrical ground. A p-type doped ridge 218 confines the driving current, which energizes just a portion of the laser active region 210 below the ridge. This arrangement creates sufficient current density to initiate and maintain lasing.

Optical modulator 204 comprises a modulator active region 220, a p-side electrode 222, a n-side electrode 224, and ridge 218. Modulator active region 220 is another epitaxially-grown layered structure that preferably includes quantum wells. A potential (V_{OM}⁺ and V_{OM}⁻ in FIG. 1) is applied across p-side electrode 222 and n-side electrode 224. Ridge 218 confines the applied electric field to a portion of modulator active region 220 below the ridge, thereby enhancing the optical modulation, which is by absorption in this example.

A passive waveguide 226 laterally confines the laser beam propagating between laser 202 and optical modulator 204. Ridge 218 provides horizontal waveguiding of the laser beam within laser 202 and optical modulator 204. The laser beam is vertically optically guided due to the higher refractive indices of laser active region 210, passive waveguide 226, and modulator active region 220 compared to the refractive indices of layer 208 and ridge 218. Lateral confinement of the laser beam within an effective waveguide 228 is depicted in the drawing. The depicted waveguide having a ridge geometry is convenient, but other types of waveguide are envisaged, such as a channel waveguide having a high refractive index core.

A modulated laser beam 230 propagates from optical modulator 204 in operation. Modulated laser beam 230 transmitted through optical modulator 204 may be coupled into an optical fiber. For example, an optical fiber connecting a transceiver containing EML 200 to another transceiver.

Substrate 206 and layer 208 have been partially etched between laser 202 and optical modulator 204. In the example depicted in FIG. 2, just a narrow isthmus of substrate 206 and layer 208 remains between the two trenches formed by this etching. This narrow isthmus is located under ridge 218 and passive waveguide 226. The laser beam propagates from laser 202 to optical modulator 204, through passive waveguide 226, which traverses the trenches.

Substrate 206 is etched to form trenches having a depth of between 2 and 4 μm. For example, a depth of 3 μm, compared to an overall substrate thickness of 100 μm. These trenches improve electrical isolation between laser 202 and optical modulator 204 by reducing the cross section of the semi-insulating substrate and conductive n-type material therebetween. Referring to FIG. 1, these trenches increase resistance R2, thereby further reducing any cross talk between transceiver channels. The example depicted in FIG. 2 has deep trenches for electrical isolation, with partial etching of both substrate 206 and layer 208. When the electrical conductivity of substrate 206 is much less than that of n-type layer 208, it may be sufficient to partially etch just layer 208, thereby forming shallower trenches between laser 202 and optical modulator 204.

The electrical isolation between laser 202 and optical modulator 204 may be further improved by spatially-selective p-type doping (not depicted) in otherwise n-type layer 208, in the narrow isthmus between laser 202 and optical modulator 204. Alternating p-type and n-type regions in layer 208 forms a series of current blocking PN junctions along this isthmus. This p-type doping in otherwise n-type layer 208 can augment electrical isolation in embodiments having a deep trench extending into substrate 206 or in embodiments having a shallower trench in just layer 208. In another embodiment, trenches are omitted and sufficient electrical isolation through layer 208 is provided by spatially-selective p-type doping to form alternating p-type and n-type regions therein.

In yet another embodiment, electrical isolation through n-type layer 208 is achieved by ion implantation. For example, implanting high-energy protons, deuterium ions, or helium ions into n-type layer 208 to reduce electrical conductivity by creating deep electron traps in the conduction band. For example, ions with energies of several 100 keV (kilo electron volts). These ions may be implanted through the whole volume of layer 208, except under passive waveguide 226, or ions may also diffuse under passive waveguide 226.

In yet another embodiment, trenches formed in layer 208 may be filled with an electrically insulating or semi-insulating material. For example, filled with the same material substrate 206 is made of. Deep trenches that protrude into the substrate and shallower trenches in just n-layer 208 may be filled in this way.

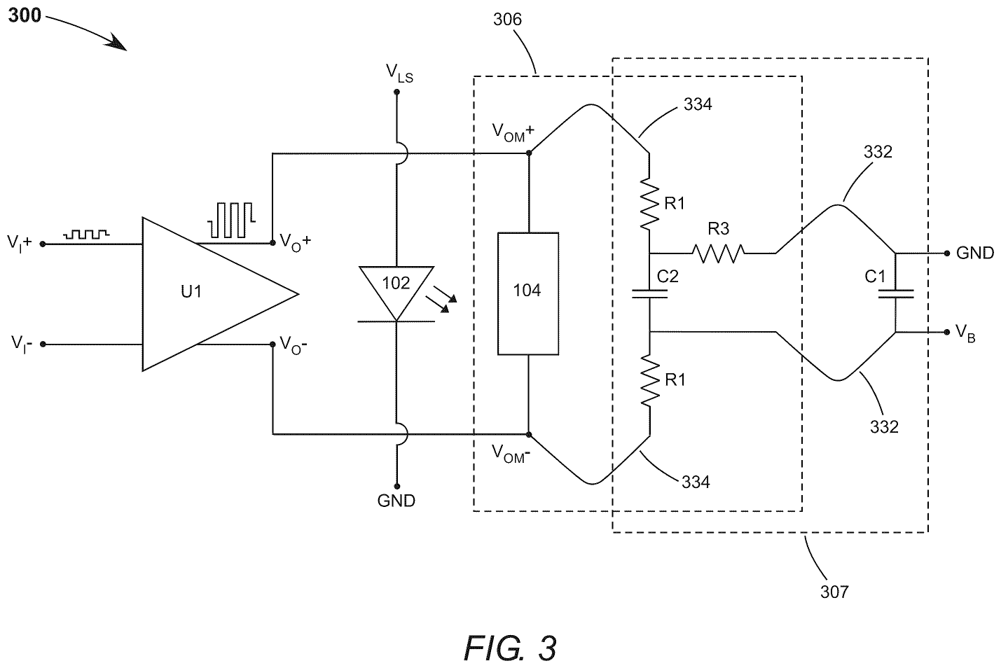

FIG. 3 schematically illustrates another embodiment of a laser transmitting device 300 in accordance with the present invention. Device 300 is similar to device 100. However, laser source 102 is located separately from optical modulator 104 and its substrate 306. A passive RF termination network 307 is electrically connected across optical modulator 104. Two resistors R1, a capacitor C2, and an optional resistor R3 of termination network 307 are located on substrate 306.

The resistors and capacitors of termination network 107 (in FIG. 1) or 307 (in FIG. 3) together with optical modulator 104 electrically terminate the high-frequency circuit including differential amplifier U1. This high-frequency circuit provides the rapidly-modulated potential driving optical modulator 104. Locating termination off substrate 106 (in device 100) creates opportunities for cross talk, by coupling high-frequency signal into the circuits of other channels. Device 300 minimizes such cross talk by terminating the high-frequency signal on substrate 306. However, it is not practical to incorporate a capacitor as large as C1 into the structure deposited on substrate 306 and to do so may add unwanted inductance. Instead, capacitor C2 is located on substrate 306 and has a much smaller capacitance than capacitor C1. C1 may have a capacitance greater than 10 nF and C2 may have a capacitance less than 500 pF (pico farad). For example, C1 has a capacitance of 100 nF, while C2 has a capacitance of 50 pF. Together, capacitors C1 and C2 maintain a desired bias potential across optical modulator 104 during operation.

Isolation of the high-frequency signal is further enhanced by the inductance of connectors 332 between capacitors C1 and C2. By way of example, connectors 332 may deliberately be made with wire bonds. At high frequencies, the inductance of connectors 332 means the termination of the modulated potential effectively just includes the smaller capacitor C2. This behavior helps to overcome the inherent frequency dependent loss in the RC circuit and thus maintains a desired modulation potential at higher frequencies (for example, at frequencies higher than 500 MHz).

To further overcome frequency-dependent losses, connectors 334 between optical modulator 104 and resistors R1 may deliberately be made more inductive. Again, connectors 334 may be made with wire bonds. Connectors 334 may have an inductance of a few hundred pico henry. For example, the inductance may be 300 pH (which would correspond to a wire bond length of about 700 μm), or 150 pH. At higher frequencies, this inductance maintains a desired differential potential across optical modulator 104. Device 300 including inductive connectors 332 and 334 has a broader operating bandwidth and optical modulator 104 provides more consistent absorption changes across that bandwidth.

Optional resistor R3 may be included in termination network 307 to suppress resonances between capacitor C2 and connectors 332. Resistor R3 introduces a small loss at high frequencies. For example, at frequencies higher than 500 MHz. A resistance of just a few ohms in resister R3 may provide sufficient damping of such high-frequency resonances. For example, a resistance of 2 Ω.

Returning to FIGS. 1 and 2, the electrical connections from differential amplifier U1 to optical modulator 204 may alternatively be formed with lumped electrodes. That is, a node-to-node connection from U1 to p-side electrode 222, and a node-to-node connection from U1 to n-side electrode 224. The lumped electrodes may be formed on top of electrodes 222 and 224. However, the laterally extending metal of lumped electrodes over underlying materials introduces unwanted capacitance, which reduces the accessible modulation bandwidth. The RC constant of each lumped electrode induces an RF reflection at high frequencies. Equivalently, each lumped electrode causes unwanted low-pass filtering.

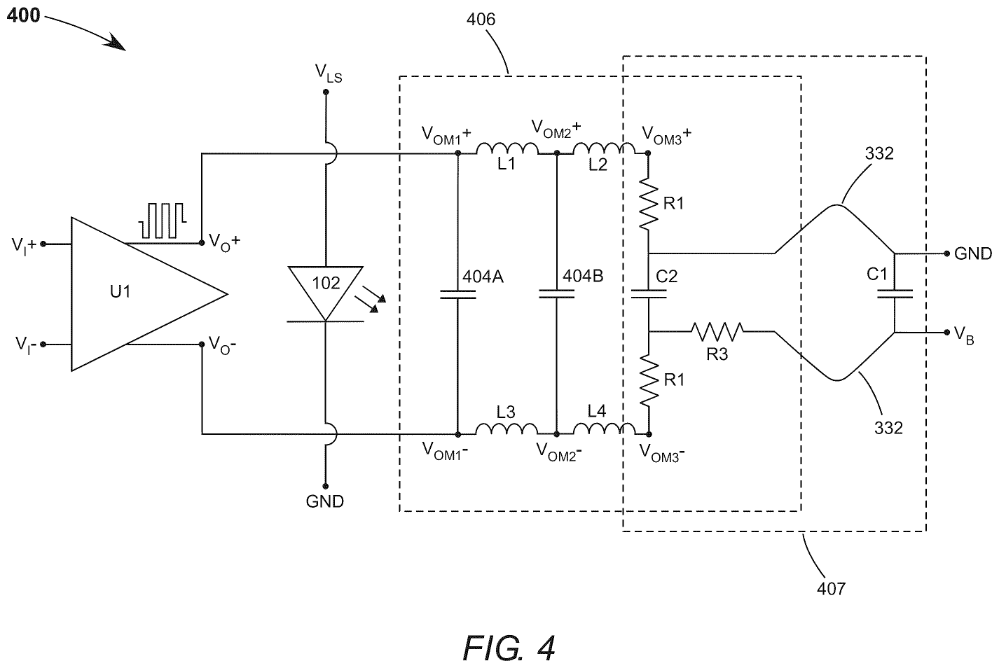

FIG. 4 schematically illustrates another embodiment of a laser transmitting device 400 in accordance with the present invention. FIG. 4 is similar to device 300, but has the optical modulation function divided between two modulator segments 404A and 404B. A laser beam from laser source 102 is intercepted by modulator segments 404A and 404B, which cooperatively modulate the power of the laser beam by partial absorption.

Modulator segments 404A and 404B are depicted in FIG. 4 as capacitors, which represents the capacitance they present to the driver circuit. In device 400, modulator segment 404A, modulator segment 404B, and a passive RF termination network 407 are electrically connected by inductors L1-L4. Such a sequence of parallel capacitors electrically connected by inductors forms a transmission line. Essentially, the inductance compensates for the capacitance of each optical modulator, allowing the optical modulators to be driven differentially by U1 with minimal reflection losses at higher frequencies and further increasing the accessible modulation bandwidth. Although not depicted in FIG. 4, each of modulator segments 404A and 404B has a fixed resistance in series with the capacitance and a variable resistance in parallel with the capacitance. The variable resistance is determined by the optical power absorbed by each optical modulator.

The optical modulation function may be divided into additional modulator segments, more than the two depicted, with each modulator segment paired with two inductors. Each modulator segment partially absorbs the laser beam in response to the modulated potential applied by differential amplifier U1. Collectively, the modulator segments in such a segmented optical modulator regulate transmission of the laser beam provided by laser 102. In device 400, modulator segments 404A and 404B, inductors L1-L4, and those components of termination network 407 that provide high-frequency termination are located on a common substrate 406.

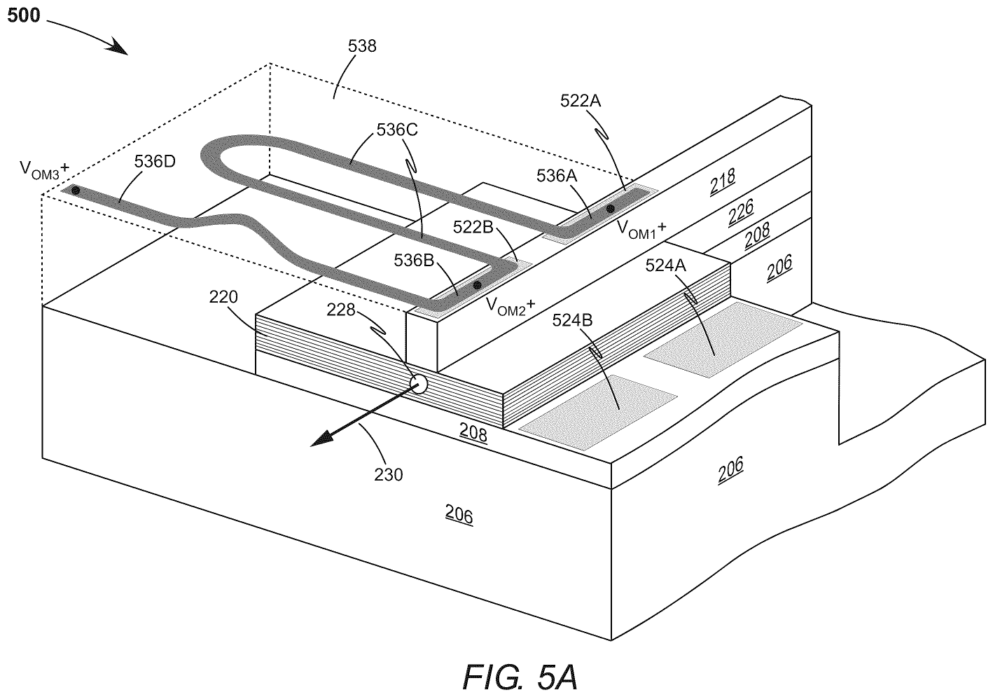

FIGS. 5A and 5B are overlapping perspective views schematically illustrating another embodiment of externally modulated laser 500. EML 500 may be implemented with laser 202 on substrate 206, as depicted in FIG. 2. Alternatively, EML 500 may be implemented with laser source 102 located separately, as depicted in FIG. 4. EML 500 is an embodiment having a segmented optical modulator, which is similar to device 400. P-side electrodes 522A and 522B and n-side electrodes 524A and 524B define two modulator segments of the optical modulator. These modulator segments 504A and 504B are essentially individual optical modulators. In EML 500, modulator segments 504A and 504B are arranged to collectively modulate the transmitted laser beam intensity, thereby providing a portion of the transmitted laser beam that is regulated by the output signal. The material therebetween is a passive waveguide, which transmits the laser beam with low optical loss. However, transmission through the passive waveguide is not regulated by the output signal. Modulator segments 504A and 504B may be optically coupled through modulator active region 220, as depicted, or through a discrete passive waveguide located therebetween.

Modulator segments 504A and 504B and differential driver U1 are electrically connected on the p-side by a traveling-wave electrode comprising four segments 536A-536D. These segments are deposited on top of a polymer layer 538, which may be made of benzocyclobutene (BCB) or another low-dielectric-constant polymer material. Polymer layer 538 provides a convenient surface to metalize and thereby form the traveling-wave electrode. Polymer layer 538 may fill the volume between the traveling-wave electrode and substrate 206. Where there are structures on substrate 206, polymer layer 538 may fill the volume between the traveling-wave electrode and these underlying structures. In FIG. 5A, a portion of polymer layer 538 directly overlays substrate 206, while another portion of polymer layer 538 overlays a structure comprising layer 208 and modulator active region 220.

Modulator segments 504A and 504B and differential driver U1 are electrically connected on the n-side by another traveling-wave electrode comprising four segments 540A-540D. These are deposited on top of another polymer layer 542, which may also be made of BCB. Dashed lines indicate the outlines of polymer layers 538 and 542 in the drawings. In FIG. 5B, polymer layer 542 directly overlays substate 206.

Electrode segments 536A and 536B are, respectively, connected to p-side electrodes 522A and 522B. Electrode segment 536C meanders between electrode segments 536A and 536B. The circuitous path is contrived to achieve the required inductance L1 in FIG. 4. Similarly, electrode segment 536D meanders to achieve the required inductance L2 in FIG. 4. Electrode segments 540A and 540B are connected to n-side electrodes 524A and 524B, respectively. Electrode segments 540C and 540D meander to achieve the required inductances L3 and L4, respectively. The output of differential amplifier U1 is connected between electrode segments 536A and 540 A. Nodes identified in FIG. 4 are also identified in FIGS. 5A and 5B to facilitate comparison.

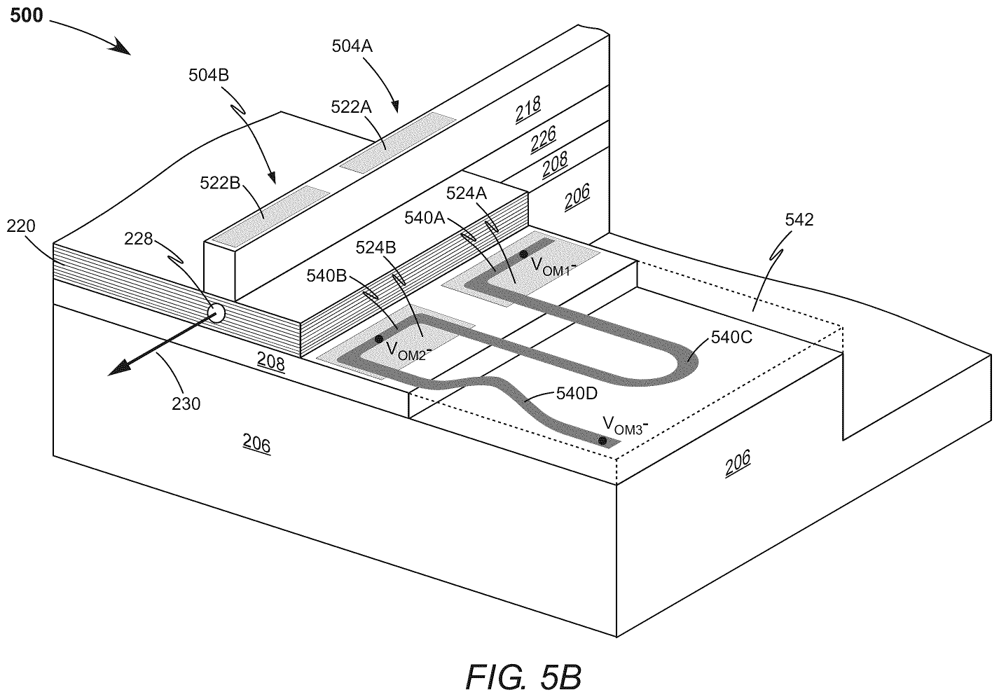

FIG. 6 is a cross-sectional view schematically illustrating another embodiment of externally modulated laser 600. EML 600 comprises EML 500, three resistors 644-648, and a capacitor 650. The cross section depicted includes electrode segments 536D and 540D of FIGS. 5A and 5B. Electrode segment 536D directly overlays polymer layer 538, which has a thickness 538T between substrate 206 and electrode segment 536D. Electrode segment 540D directly overlays polymer layer 542.

Resistors 644 and 646 are located at distal ends of electrode segments 536D and 540D, respectively. Resistors 644 and 646 correspond to resistors R1 in FIG. 4 and resistor 648 corresponds to resistor R3 in FIG. 4. The distal end of electrode segment 536D, on the p-side of the optical modulators, is connected to electrical ground through resistor 644. The distal end of electrode segment 540D, on the n-side of the optical modulators, is serially connected to bias potential V_{B} through resistors 646 and 648. Capacitor 650 corresponds to capacitor C2 in FIG. 4. One side of capacitor 650 is disposed on substrate 206. Capacitor 650 is electrically connected between resistors 646 and 648 and electrical ground.

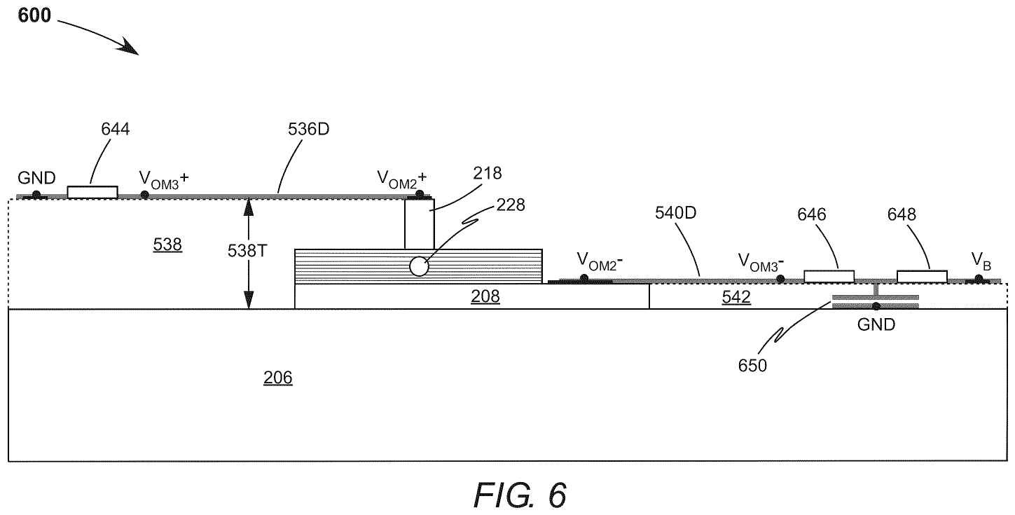

FIG. 7 is a cross-sectional view schematically illustrating another embodiment of externally modulated laser 700. EML 700 is similar to EML 600, with an exception that layer 208 extends over all of substrate 206 underlying the electrode segments on the p-side of the optical modulators. EML 700 differs from EML 600 in that EML 600 has a portion of layer 208 omitted or etched away. The n-type doped material of layer 208 interposed between the electrode segments and substrate 206 introduces capacitance and reduces inductance. A way to mitigate this increased capacitance and reduced inductance is to increase a thickness 738T of a polymer layer 738 between substrate 206 and an electrode segment 736D. Electrode segment 736D may be modified accordingly, as depicted. However, the additional material of polymer layer 738 in EML 700 compared to polymer layer 538 in EML 600 adds cost and unwanted mechanical strain. This strain may cause changes in materials mechanically connected to polymer layer 738, thereby degrading the performance and reliability of EML 700. In extreme cases, this strain may induce cracking of polymer layer 738 itself.

Polymer layer 738 of EML 700 may have a thickness 738T of many microns. For example, a thickness 738T of 9 μm. In contrast, polymer layer of 538 of EML 600 may have a thickness 538T of just a few microns. For example, a thickness less than 5 μm, such as a thickness 538T of 3 μm. For this reason, EML 600 may be preferable to EML 700. It is preferable to maximize the portion of polymer layer 538 that directly overlays substrate 206 and minimize any portion that overlays a n-type doped layer. For example, greater than 50% of polymer layer 538 directly overlays substate 206, or more favorably greater than 75% of polymer layer 538 directly overlays substate 206.

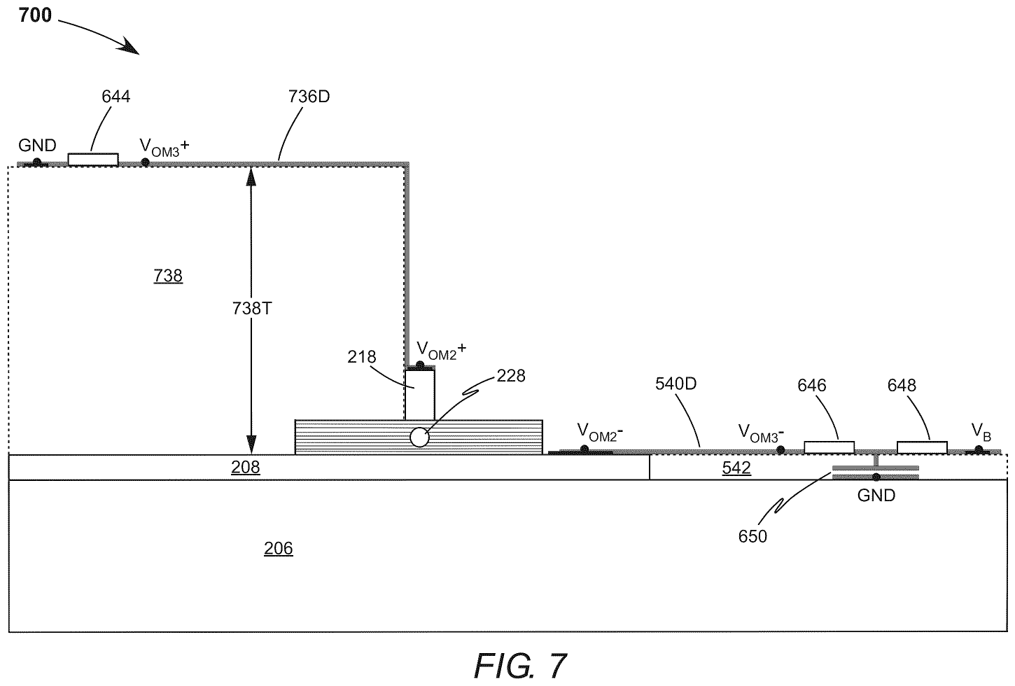

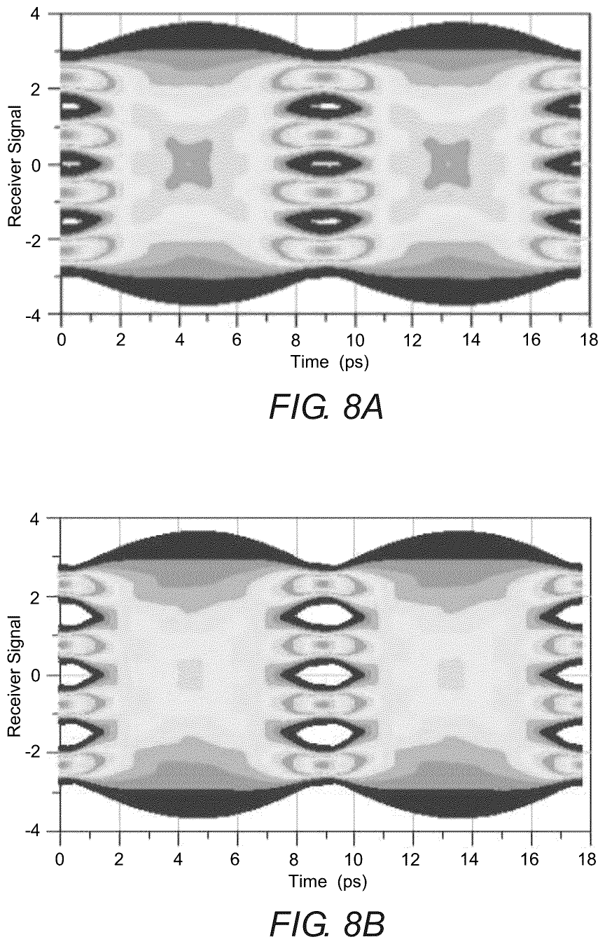

FIGS. 8A and 8B are “eye diagrams” depicting advantages of laser transmitting devices that minimize cross talk between channels by locating a termination network close to an optical modulator. The diagram in FIG. 8B simulates a transceiver having four operational laser transmitting devices 300, as depicted in FIG. 3, each operating at 200 Gb/s device and with PAM4 encoding. Each device has resistors R1 (30 Ω), capacitor C2 (50 pF), resistor R3 (2 Ω), and optical modulator 104 located on a common substrate 306. Here, optical modulator 104 is an EAM. Capacitor C1 (100 nF) is not located on substrate 306. Connectors 332 and connectors 334 (300 pH) are wire bonds that provide beneficial electrical isolation at high frequencies, gain peaking, and bandwidth extension, as described herein above. Using these components in the arrangement depicted in FIG. 3, the differential drive signal applied by differential amplifier U1 is cleanly terminated on substrate 306 for frequencies above 1 GHz, maintaining good signal integrity.

For comparison, the diagram in FIG. 8A simulates an equivalent transceiver also having four laser transmitting devices operating at 200 GHz and PAM4. These devices terminate the differential drive signal entirely off the chip supporting the EAM optical modulator, which is similar to the arrangement of termination network 107 of device 100 depicted in FIG. 1.

FIGS. 8A and 8B depict signal density on a graph of receiver signal vs. time. The receiver signal has arbitrary units, but represents four PAM4 signal levels. High signal density is depicted by dark shading and low signal density by light shading. Both simulations include transmitter-to-receiver cross talk. The eyes in FIG. 8B are much more open than the eyes in FIG. 8A, because there is significantly less parasitic transmitter signal leaking onto the receiver signal. In FIG. 8B, the transmitter signals are well isolated on respective substrate 306 of each laser transmitter device 300. At these short time scales and high modulation frequencies, terminating the differential drive signal on the same substrate as the optical modulator and in close proximity thereto significantly improves receiver operation by practically eliminating noise caused by parasitic transmitter signal.

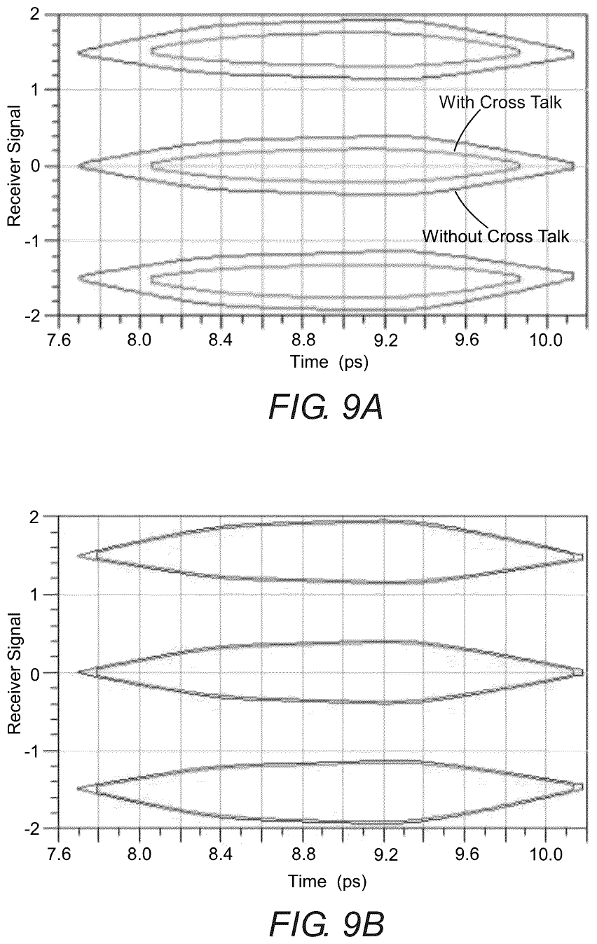

FIGS. 9A and 9B depict bit error rate (BER) contours in simulations of the same respective transceivers as FIGS. 8A and 8B. It should be noted that in FIGS. 9A and 9B the time scales are expanded to better resolve receiver signal around the set of eyes occurring at about 9 ps in FIGS. 8A and 8B. All contours in FIGS. 9A and 9B correspond to a BER of 2×10^{-4,} either with or without transmitter-to-receiver cross talk included in the simulation. In the transceiver depicted in FIG. 9A, there is considerably higher BER closer to the center of each eye due to cross talk, indicating significantly less signal integrity at these high data rates. In contrast, the contours with and without cross talk in FIG. 9B are almost indistinguishable, indicating good receiver sensitivity and signal integrity, even when all four transmitters operate at high data rates. Again, terminating the differential drive signal on the same substrate as the optical modulator in all of laser transmitting devices 300 of FIG. 9B improves the fidelity of high-rate optical data transmission. This improvement can be attributable mostly to the high-frequency termination provided by capacitor C2 located on common substrate 306 and in close proximity to optical modulator 104. The inductance of connections 332 further confines the differential drive signal to substrate 306.

In summary, a compact high-data-rate laser transmitter is disclosed with a laser source and a differentially driven optical modulator fabricated on a common insulating or semi-insulating substrate. Sufficient electrical isolation between the laser source and the optical modulator is achieved by etching trenches therebetween. Electrical isolation may be improved by spatially-selective p-type doping or ion implantation in a n-type layer located between the optical components and the substrate. Cross talk imposed on other transmitting and receiving channels is minimized by electrically terminating the high-frequency drive signal on the common substrate. Electrically connecting a plurality of optical modulators or modulator segments and a termination network with a transmission line comprising traveling-wave electrodes is compact and avoids adding capacitance to the drive circuit. A transmission line having inductance in the electrical connections compensating for capacitance in the optical modulators or modulator segments maintains signal integrity and minimizes signal losses.

The present invention is described above in terms of a preferred embodiment and other embodiments. The invention is not limited, however, to the embodiments described and depicted herein. Rather, the invention is limited only by the claims appended hereto.

What is claimed is:

1. A laser transmitting device, comprising:
an electrically insulating or semi-insulating substrate;
a laser source located on the substrate that produces a laser beam;
at least two optical modulators located on the substrate and intercepting the laser beam, each optical modulator having an n-side and a p-side;
a differential amplifier having an electrical input and an electrical output, the electrical output applied differentially across the optical modulators, the electrical output regulating transmission of the laser beam through the optical modulators;
a termination network; and
first and second traveling-wave electrodes, the first traveling-wave electrode inductively connecting the n-sides of the optical modulators, the second traveling-wave electrode inductively connecting the p-sides of the optical modulators, and the first and second traveling-wave electrodes electrically connected to the termination network.

2. The laser transmitting device of claim 1, wherein there is at least 1 kΩ of electrical resistance between the laser source and the optical modulators.

3. The laser transmitting device of claim 1, wherein the substrate is made of a semiconductor material.

4. The laser transmitting device of claim 1, wherein the optical modulators cooperatively regulate transmission of the laser beam by partially absorbing the laser beam or by partially reflecting the laser beam.

5. The laser transmitting device of claim 1, wherein the at least two optical modulators are modulator segments of a segmented optical modulator.

6. The laser transmitting device of claim 1, wherein the differential amplifier or the termination network is located off the substrate.

7. The laser transmitting device of claim 1, wherein the first traveling-wave electrode includes a first electrode segment that meanders between the n-sides of the optical modulators and the second traveling-wave electrode includes a second electrode segment that meanders between the p-sides of the optical modulators.

8. The laser transmitting device of claim 7, wherein each electrode segment overlays a polymer layer, which fills a volume between the substrate and the respective electrode segment.

9. The laser transmitting device of claim 8, wherein the polymer layer is made of benzocyclobutene (BCB).

10. The laser transmitting device of claim 8, wherein a portion greater than 50% of the polymer layer directly overlays the substrate.

11. The laser transmitting device of claim 10, wherein the portion of the polymer layer directly overlaying the substrate has a thickness of less than 5 μm.

12. The laser transmitting device of claim 1, wherein the laser source produces the laser beam as a continuous wave laser beam.

13. The laser transmitting device of claim 1, wherein the electrical input and electrical output comprise a data signal having a data rate greater than 10 Gb/s.

14. An optical transceiver device including the laser transmitting device of claim 1, wherein the laser beam transmitted through the optical modulators is coupled into an optical fiber.

15. A laser transmitting device, comprising:
an electrically insulating or semi-insulating substrate;
a laser source located on the substrate that produces a laser beam;
an optical modulator located on the substrate and intercepting the laser beam;
a differential amplifier having an electrical input and an electrical output, the electrical output applied differentially across the optical modulator, the electrical output regulating transmission of the laser beam through the optical modulator; and
a termination network electrically connected across the optical modulator, the termination network including first and second capacitors, wherein the first and second capacitors are each in parallel with the optical modulator, the first and second capacitors cooperatively maintaining a bias potential across the optical modulator, the first capacitor located off the substrate, the second capacitor located on the substrate, and capacitance of the first capacitor being greater than capacitance of the second capacitor.

16. The laser transmitting device of claim 15, wherein the first and second capacitors are electrically connected to each other by wire bonds.

17. The laser transmitting device of claim 15, wherein an electrical connection between the first and second capacitors includes a resistor that suppresses resonances between the first and second capacitors.

18. The laser transmitting device of claim 15, wherein the first capacitor has a capacitance greater than 10 nF (nano farad) and the second capacitor has a capacitance less than 500 pF (pico farad).

19. The laser transmitting device of claim 15, wherein there is at least 1 kΩ of electrical resistance between the laser source and the optical modulators.

20. The laser transmitting device of claim 15, wherein the substrate is made of a semiconductor material.

21. The laser transmitting device of claim 15, wherein the optical modulator regulates transmission of the laser beam by partially absorbing the laser beam or by partially reflecting the laser beam.

22. The laser transmitting device of claim 15, wherein the differential amplifier is located off the substrate.

23. The laser transmitting device of claim 15, wherein the laser source produces a continuous wave laser beam.

24. The laser transmitting device of claim 15, wherein the optical modulator is a segmented optical modulator.

25. The laser transmitting device of claim 24, wherein modulator segments in the segmented optical modulator are electrically connected by traveling-wave electrodes.

26. The laser transmitting device of claim 15, wherein the electrical input and electrical output comprise a data signal having a data rate greater than 10 Gb/s.

27. An optical transceiver device including the laser transmitting device of claim 15, wherein the laser beam transmitted through the optical modulator is coupled into an optical fiber.
